(19) United States
(12) Patent Application Publication
(10) Pub. No.: US 2025/0183170 A1
(43) Pub. Date: Jun. 5, 2025

(54) SEMICONDUCTOR DEVICE AND SEMICONDUCTOR PACKAGE INCLUDING THE SAME

(71) Applicant: Samsung Electronics Co., Ltd., Suwon-si (KR)

(72) Inventors: Kyungsoo LEE, Suwon-si (KR); Bongwee YU, Suwon-si (KR)

(73) Assignee: Samsung Electronics Co., Ltd., Suwon-si (KR)

(21) Appl. No.: 18/796,664

(22) Filed: Aug. 7, 2024

(30) Foreign Application Priority Data
Dec. 1, 2023 (KR) 10-2023-0172652

(51) Int. Cl. H01L 23/528; H01L 23/00; H01L 23/31; H01L 23/498; H01L 23/522; H01L 25/065; H05K 1/18

(52) U.S. Cl. CPC H01L 23/5283; H01L 23/3128; H01L 23/49833; H01L 23/5226; H01L 24/16; H05K 1/181; H01L 24/08; H01L 24/32; H01L 24/73; H01L 25/0657; H01L 2224/08145; H01L 2224/16148; H01L 2224/16227; H01L 2224/32145; H01L 2224/73204; H01L 2924/1815

(57) ABSTRACT

A semiconductor device includes at least one semiconductor chip that includes a semiconductor substrate having a front surface and a rear surface, a device portion on the front surface, a first connection line on the device portion, a first pad portion on the first connection line and including a plurality of first pads, a second connection line on the rear surface and including a power distribution network, and a second pad portion on the second connection line and including a plurality of second pads. At least a portion of the second pads may be connected to the power management network to apply power supply voltage to the device portion through the power distribution network.

### CROSS-REFERENCE TO RELATED APPLICATION(S)

This U.S. non-provisional application claims priority under 35 USC § 119 to Korean Patent Application No. 10-2023-0172652, filed on Dec. 1, 2023, in the Korean Intellectual Property Office, the disclosure of which is herein incorporated by reference in its entirety.

### BACKGROUND

Example embodiments relate to semiconductor devices and semiconductor packages including the same.

As the storage capacity of semiconductor chips increases, there is a growing demand for lighter and thinner semiconductor packages including semiconductor chips. Semiconductor chips include various integrated circuits, such as various devices including thin film transistors, on a silicon wafer. To drive such semiconductor chips rapidly and stably, efficient transfer of power and signal is a major concern for semiconductor packaging. For example, attempts are being made to increase the integration of semiconductor chips by applying a back-side power distribution network (BS-PDN). However, additional methods for improving such a structure are required to achieve more efficient power distribution.

### SUMMARY

Example embodiments provide semiconductor devices for efficiently providing power and signals to a semiconductor chip and semiconductor packages including the same.

According to an example embodiment, a semiconductor device includes at least one semiconductor chip. The semiconductor chip includes a semiconductor substrate having a front surface and a rear surface, a device portion on the front surface, a first connection line on the device portion, a first pad portion on the first connection line and including a plurality of first pads, a second connection line on the rear surface and including a power distribution network, and a second pad portion on the second connection line and including a plurality of second pads. At least a portion of the second pads is connected to the power distribution network to apply power supply voltage to the device portion through the power distribution network.

In an example embodiment, the semiconductor substrate may include at least one through-substrate via penetrating through the front surface and the rear surface of the semiconductor substrate and connecting the second connection line and the device portion to each other and the second connection line and the first connection line to each other.

In an example embodiment, each of the first connection line and the second connection line may include conductive interconnections on at least one layer and conductive vias connecting the conductive interconnections to each other.

In an example embodiment, the semiconductor device may further include first connectors on the first pad portion and configured to be connected to an external component, and second connectors on the second pad portion and configured to be connected to an external component.

In an example embodiment, a pitch of the first connectors may be different from a pitch of the second connectors.

In an example embodiment, the first connectors and the second connectors may include one of C4 bumps, micro bumps, conductive pillars, solder balls for ball grid array, cored solder balls, or copper-cupper bonding.

According to an example embodiment, a semiconductor device includes a first semiconductor chip and a second semiconductor chip stacked sequentially. Each of the first semiconductor chip and the second semiconductor chip includes a semiconductor substrate having a front surface and a rear surface, a device portion on the front surface, a first connection line on the device portion, a first pad portion on the first connection line and comprising a plurality of first pads, a second connection line on the rear surface and comprising a power distribution network, and a second pad portion on the second connection line and comprising a plurality of second pads. At least a portion of the second pads may be connected to the power distribution network to apply a power supply voltage to the device portion through the power distribution network.

In an example embodiment, the semiconductor device may further include a first connector on the first pad portion and a second connector on the second pad portion. The first connector and the second connector may include one of a C4 bumps, micro bumps, conductive pillars, solder balls for ball grid array, cored solder balls, or copper-cupper bonding.

In an example embodiment, the first semiconductor chip and the second semiconductor chip are stacked such that a front surface of the first semiconductor chip and a front surface of the second semiconductor chip oppose each other, stacked such that a rear surface of the first semiconductor chip and a front surface of the second semiconductor chip oppose each other, or stacked such that a rear surface of the first semiconductor chip and a rear surface of the second semiconductor chip oppose each other.

In an example embodiment, the first semiconductor chip and the second semiconductor chip may have different sizes.

According to an example embodiment, a semiconductor device package includes a first package substrate, a second package substrate, and at least one semiconductor chip between the first package substrate and the second package substrate. The at least one semiconductor chip includes a semiconductor substrate having a front surface and a rear surface, a device portion on the front surface, a first connection line on the device portion, a pad portion on the first connection line and including a plurality of first pads, a second connection line on the rear surface and including a power distribution network, and a second pad portion on the second connection line and including a plurality of second pads. At least a portion of the second pads may be connected to the power distribution network to apply a power supply voltage to the device portion through the power distribution network.

In an example embodiment, the at least one semiconductor chip may include a first semiconductor chip and a second semiconductor chip, the first semiconductor chip and the first package substrate may be connected by a connector, and the second semiconductor chip and the second package substrate may be connected by a connector.

In an example embodiment, the semiconductor device package may further include a molding layer filling a space between the first package substrate and the second package substrate.

In an example embodiment, at least one of the first package substrate or the second package substrate may include a redistribution structure and external connectors connected to the redistribution structure.

According to an example embodiment, a semiconductor package module includes a first module substrate, a second module substrate, the aforementioned semiconductor device package between the first module substrate and the second module substrate, and at least one semiconductor package on at least one of the first module substrate or the second module substrate.

In an example embodiment, the semiconductor package module may further include an interposer substrate between the first module substrate and the second module substrate and connecting the first module substate and the second module substrate.

In an example embodiment, each of the first module substrate and the second module substrate may be a printed circuit board.

In an example embodiment, the semiconductor package may include a first power management integrated circuit (PMIC) on the first module substrate and a second PMIC on the second module substrate.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a cross-sectional view of a semiconductor device according to an example embodiment.

FIG. 2A is an enlarged cross-sectional view of P1 of FIG. 1, and FIG. 2B is an enlarged cross-sectional view of P2 of FIG. 1.

FIG. 3A is a cross-sectional view conceptually illustrating transfer of power and signal depending on paths in a semiconductor device according to the related art, and FIG. 3B is a cross-sectional view conceptually illustrating transfer of power and signal depending on paths in a semiconductor device according to an example embodiment.

FIGS. 4A to 4C are cross-sectional views of semiconductor devices according to some example embodiments, which illustrate that a first pad portion, a second pad portion, and/or a connector are formed to be different from those in the above-described example embodiments.

FIGS. 5A and 5B are cross-sectional views of an example of a semiconductor device according to some example embodiments in which two semiconductor chips are vertically stacked.

FIG. 6 is a cross-sectional view of a stacked structure of a semiconductor device according to an example embodiment.

FIG. 7 is a cross-sectional view of a stacked structure of a semiconductor device according to an example embodiment.

FIG. 8 is a cross-sectional view of a semiconductor device according to an example embodiment, which illustrates a cross-section in which two semiconductor chips having different sizes are stacked.

FIG. 9 is a cross-sectional view of a semiconductor package according to an example embodiment.

FIG. 10 is a conceptual diagram illustrating a semiconductor package module according to an example embodiment.

### DETAILED DESCRIPTION

Some example embodiments provide semiconductor devices and semiconductor packages including the same. Some example embodiments provide semiconductor packages having a package-on-package (POP) structure.

In general, an integrated circuit (IC) is formed by forming an electronic circuit on a semiconductor material such as silicon. An IC may include a large number of transistors, capacitors, resistors, and other electronic components that are integrated onto a single silicon die (or a single semiconductor chip). Such an IC may be implemented in various forms, for example, as a three-dimensional integrated circuit (3D IC), a 2.5D IC, or a multi-chip module. Some example embodiments relate to configurations for transferring power and signal (referring to electrical signals other than the power) to a plurality of semiconductor chips included in a 3D IC, a 2.5D IC, a multi-chip module, or the like, and particularly to a placement of a power distribution network transferring power.

Hereinafter, some example embodiments will be described in detail with reference to the accompanying drawings. The same reference numerals are used for the same components in the drawings, and duplicate descriptions thereof will be omitted.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

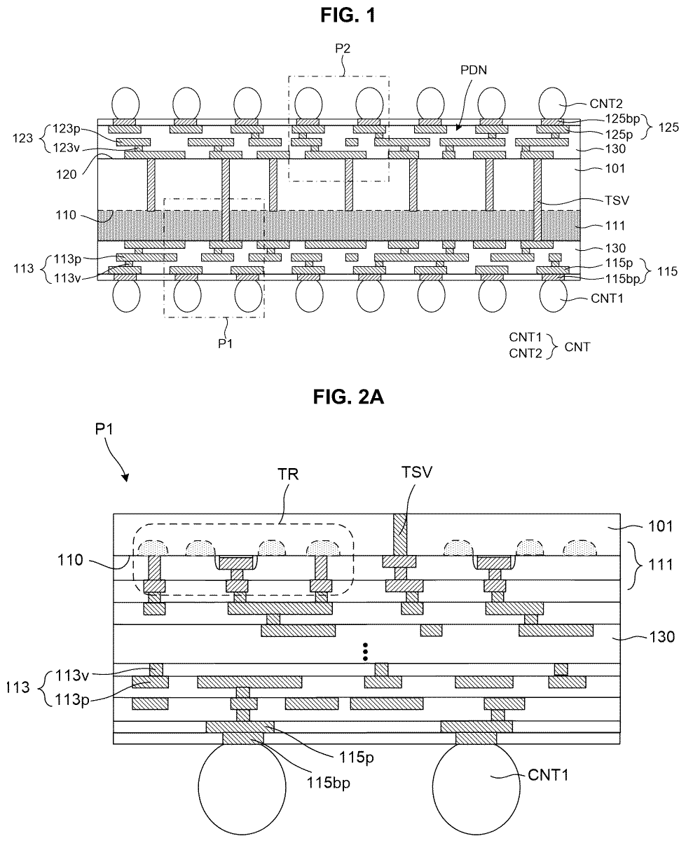

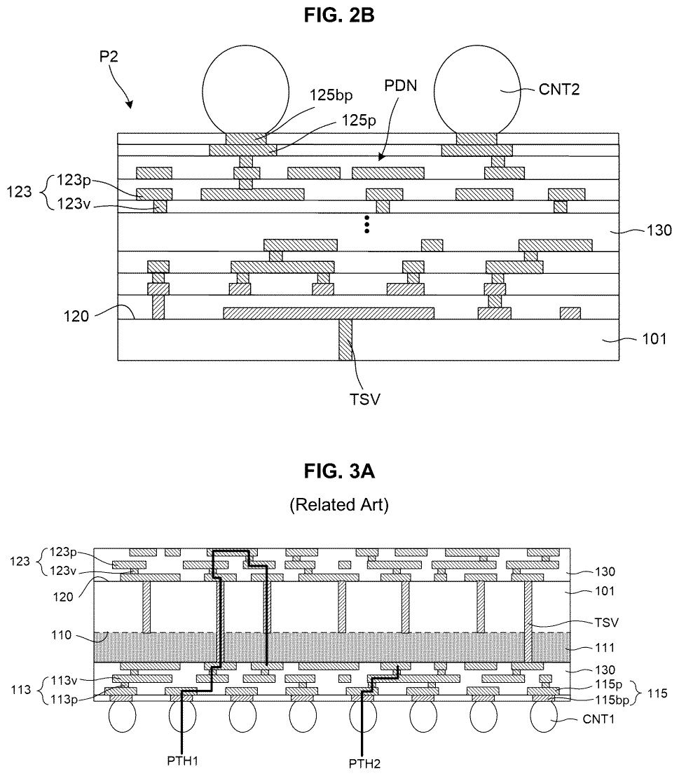

FIG. 1 is a cross-sectional view of a semiconductor device according to an example embodiment. FIG. 2A is an enlarged cross-sectional view of P1 of FIG. 1, and FIG. 2B is an enlarged cross-sectional view of P2 of FIG. 1.

Referring to FIGS. 1, 2A, and 2B, a semiconductor device according to an example embodiment may include at least one semiconductor chip.

The semiconductor chip may be a logic semiconductor chip, a memory semiconductor chip, or a combination thereof. For example, a logic semiconductor chip may be an application processor (AP), a microprocessor, a central processing unit (CPU), a controller, a graphics processing unit (GPU), a system-on-a-chip (SoC), or an application specific integrated circuit (ASIC). Further, a memory semiconductor chip may be a volatile memory such as a dynamic random access memory (DRAM) or a static random access memory (SRAM), or a nonvolatile memory such as a phase-change random access memory (PRAM), a magneto-resistive random access memory (MRAM), a ferroelectric random access memory (FeRAM), or a resistive random access memory (RRAM).

The semiconductor chip may include a semiconductor substrate 101, a device portion 111 provided on the semiconductor substrate 101, a first connection line 113 and a second connection line 123 connected to the device portion 111, and a first pad portion 115 and a second pad portion 125 provided to be connected to external components through the first connection line 113 and the second connection line 123. A connector CNT (e.g., CNT1 and CNT2) may be provided on each of the first pad portion 115 and the second pad portion 125 to be electrically connected to the outside (e.g., connected to an external component).

The semiconductor substrate 101 has a front surface 110 and a rear surface 120. The front surface 110 and the rear surface 120 are surfaces opposing each other, and may be referred to as a first surface and a second surface. The front surface 110 and the rear surface 120 are relative concepts, and the front surface 110 refers to a surface of the semiconductor substrate 101 on which the device portion 111 is formed, and the rear surface 120 refers to a surface opposing the front surface 110.

The semiconductor substrate 101 may be, for example, a doped or undoped silicon (Si) substrate. In an example embodiment, the semiconductor substrate 101 may include other semiconductor material, such as germanium, a compound semiconductor including silicon carbide, gallium arsenic, gallium phosphide, indium phosphide, indium arsenide, and/or indium antimonide, an alloy semiconductor including SiGe, GaAsP, AlInAs, AlGaAs, GaInAs, GaInP, and/or GaInAsP, or combinations thereof. The semiconductor substrate 101 may be formed to have a single-layer structure or a multilayer structure.

The device portion 111 may be a region including various ICs within the semiconductor substrate 101. The device portion 111 may be provided on the front surface 110 of the semiconductor substrate 101 and may include various microelectronic devices. Microelectronic devices may include, for example, a complementary metal-insulator-semiconductor (CMOS) transistor, a metal-oxide-semiconductor field effect transistor (MOSFET), a system large scale integration (LSI), an image sensor such as a CMOS imaging sensor (CIS), and image sensors. It may also include micro-electro-mechanical systems (MEMS), various active devices, various passive devices, or combinations of active and passive devices. For brevity of description, in FIG. 2A, a transistor TR is illustrated as a portion of the device portion 111.

The first connection line 113 may be provided on the device portion 111. The first connection line 113 may be provided as a first conductive interconnection structure having at least one layer electrically connected to the device portion 111. The first conductive interconnection structure may include an interlayer insulating layer 130 provided on the device portion 111, a first conductive pattern 113p provided on the interlayer insulating layer 130, and a first conductive via 113v penetrating through the interlayer insulating layer 130. The first conductive pattern 113p may be provided to transfer electrical signal and power in a lateral direction, and the first conductive via 113v may be provided to transfer electrical signal and power in a vertical direction. Each of the first conductive pattern 113p and the first conductive via 113v may be provided in plural, and thus the device portion 111 and the first connection lines 113 may be electrically connected in various forms, or the first connection lines 113 may be electrically connected to each other.

The interlayer insulating layer 130 may include an appropriate dielectric material such as silicon oxide, silicon nitride, silicon oxynitride, silicon carbide, or combinations thereof. In some example embodiments, the interlayer insulating layer 130 may include a dielectric material such as undoped silicate glass (USG), phosphosilicate glass (PSG), borosilicate glass (BSG), or boron-doped phosphosilicate glass (BPSG).

Each of the first conductive pattern 113p and the first conductive via 113v may be formed of various conductive materials such as tungsten, cobalt, nickel, copper, silver, gold, tin, molybdenum, zinc, platinum, aluminum, or combinations thereof.

The first conductive interconnection structure may include a plurality of layers. For example, the interlayer insulating layer 130 may be provided in plural, and each of the first conductive pattern 113p and the first conductive via 113v may be provided on the interlayer insulating layer 130 in singular or plural.

The first pad portion 115 may be provided on the first connection line 113. The first pad portion 115 may include a plurality of first pads 115p, and the first pads 115p may be connected to the first connection line 113. The first pad portion 115 may further include first bonding pads 115bpprovided on the first pads 115p, respectively, and formed in a region in which the first connector CNT1 for connection to the outside is provided.

The first pads 115p and the first bonding pads 115bp may be formed of a conductive material. Each of the first pads 115p and the first bonding pads 115bp may include a conductive material such as tungsten, cobalt, nickel, copper, silver, gold, tin, molybdenum, zinc, platinum, aluminum, or a combination thereof, or a conductive paste containing the same.

Although not illustrated, the first pads 115p and the first bonding pads 115bp may be provided on one or more passivation layers, and the one or more passivation layers may extend upwardly of a portion of the first bonding pads 115bp. In this case, an opening may be provided on the passivation layer extending to the first bonding pads 115bp, and upper surfaces of the first bonding pads 115bp may be exposed to the outside through the opening.

Solder balls may be provided on the first pad portion 115 as a first connector CNT1 for electrical connection to the outside. The first connector CNT1 may be provided to be in direct contact with the first bonding pads 115bp of the first pad portion 115 for electrical connection to an external component. For example, the solder balls may be provided to be in direct contact with the first bonding pads 115bp with the upper surfaces exposed, respectively. For example, various signals and power, or the like, may be transferred to the first pad portion 115 from the outside or transferred from the first pad portion 115 to the outside through the first connector CNT1. The first connector CNT1 may include, for example, micro bumps (MB), metal pillars, ball grid array (BGA) solder balls, other various sizes of solder balls, cored solder balls, or a combination thereof. In an example embodiment, the first connector CNT1 may include a solder ball for C4 bump (e.g., C4 solder bump). In some example embodiments in which the first connector CNT1 is formed of a solder ball for C4 bump, a reflow process, or the like, may be performed to shape a solder ball material into a desired bump shape.

The second connection line 123 may be provided on the rear surface 120 of the semiconductor substrate 101. The second connection line 123 may be connected to a through-substrate via TSV to be described later, and may be provided as a second conductive interconnection structure. The second conductive interconnection structure may include an interlayer insulating layer 130, a second conductive pattern 123p provided on the interlayer insulating layer 130, and a second conductive via 123v penetrating through the interlayer insulating layer 130. The second conductive pattern 123p may be provided to transfer an electrical signal and power in the lateral direction, and the second conductive via 123v may be provided to transfer an electrical signal and power in the vertical direction. Each of the second conductive pattern 123p and the second conductive via 123v may be provided in plural, and thus the device portion 111 and the second connection lines 123 may be electrically connected in various forms, or the second connection lines 123 may be electrically connected to each other.

The interlayer insulating layer 130 of the second conductive interconnection structure may include an appropriate dielectric material such as silicon oxide, silicon nitride, silicon oxynitride, silicon carbide, or combinations thereof, as described above. In some example embodiments, the interlayer insulating layer 130 may also include a dielectric material such as undoped silicate glass (USG), phosphosilicate glass (PSG), borosilicate glass (BSG), or boron-doped phosphosilicate glass (BPSG).

Each of the second conductive pattern 123p and the second conductive via 123v may be formed of various conductive materials such as tungsten, cobalt, nickel, copper, silver, gold, tin, molybdenum, zinc, platinum, aluminum, or combinations thereof.

In this case, the second conductive interconnection structure may include a plurality of layers. For example, the interlayer insulating layer 130 may be provided in plural, and each of the second conductive pattern 123p and the second conductive via 123v may be provided on each interlayer insulating layer 130 in singular or plural.

At least a portion of the second connection line 123 may constitute a power distribution network PDN. The power distribution network PDN may distribute and transfer power to the device portion 111. For example, the power distribution network PDN may include a second conductive pattern 123p and a second conductive via 123v as at least a portion of the second connection line 123. The second conductive pattern 123p may be a continuous or discontinuous pattern. In some example embodiments, the second conductive pattern 123p may be a ground plane or a power distribution plane.

The second pad portion 125 may be provided on the second connection line 123. At least a portion of the second pads 125p may be connected to the power distribution network PDN to apply a power supply voltage to the device portion 111 through the power distribution network PDN.

In an example embodiment, the entire second connection line 123 may be constitute the power distribution network PDN. However, example embodiments are not limited thereto, and a portion of the second connection line 123 may correspond to an interconnection for transferring a signal that does not correspond to the power distribution network PDN, for example, a control signal of a device.

The second pad portion 125 may include a plurality of second pads 125p, and the second pads 125p may be connected to the second connection line 123. The second pad portion 125 may also include second bonding pads 125bp provided on the second pads 125p, respectively.

The second pads 125p and the second bonding pads 125bp may be formed of a conductive material. Each of the second pads 125p and the second bonding pads 125bp may include a conductive material such as tungsten, cobalt, nickel, copper, silver, gold, tin, molybdenum, zinc, platinum, aluminum, or combinations thereof, or a conductive paste containing the same.

The second pads 125p and the second bonding pads 125bp may be provided on one or more passivation layers, and the one or more passivation layers may extend upwardly of a portion of the second bonding pads 125bp. In this case, an opening may be provided on the passivation layer extending to the second bonding pads 125bp, and upper surfaces of the second bonding pads 125bp may be exposed to the outside through the opening.

Solder balls may be provided on the second pad portion 125 as a second connector CNT2 for electrical connection to the outside. The second connector CNT2 may be provided to be in direct contact with the second bonding pads 125bp of the second pad portion 125 for electrical connection to external components. For example, solder balls may be provided to be in direct contact with the second bonding pads 125bp with the upper surfaces exposed, respectively. For example, various signals and power, or the like, may be transferred from the outside to the second pad portion 125 through the second connector CNT2, or transferred from the second pad portion 125 to the outside through the second connector CNT2. The second connector CNT2 may include, for example, micro bumps MB, metal pillars, ball grid array (BGA) solder balls, other various sizes of solder balls, cored solder balls, or a combination thereof. In an example embodiment, the second connector CNT2 may include a solder ball for C4 bump (e.g., C4 solder bump). In some example embodiments in which the second connector CNT2 is formed of a solder ball for C4 bump, a reflow process, or the like, may be performed to shape a solder ball material into a desired bump shape.

In an example embodiment, through-substrate vias TSVs may be provided on the semiconductor substrate 101.

The through-substrate vias TSVs may penetrate through the front surface 110 and the rear surface 120 of the semiconductor substrate 101. Each of the through-substrate vias TSVs may have one end, connected to the device portion 111 or the first connection line 113, and the other end connected to the second connection line 123. The other end of at least a portion of the through-substrate vias TSVs may be electrically connected to the power distribution network PDN in the second connection lines 123.

The through-substrate vias TSVs may be provided such that a recess is formed inside the semiconductor substrate 101 and a conductive material fills the recess. The conductive material may include tungsten, cobalt, nickel, copper, silver, gold, tin, molybdenum, zinc, platinum, aluminum, doped polysilicon, or combinations thereof.

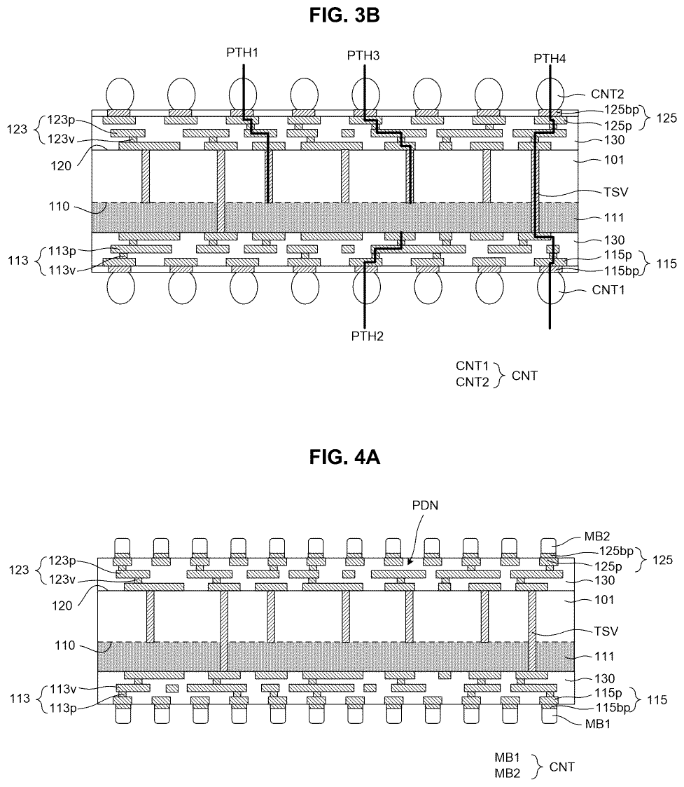

The semiconductor device having the above-described structure may facilitate the transfer of power and signal from another component to the device portion 111 or from the device portion 111 to another component. For example, the semiconductor device having the above-described structure may be advantageous in transferring power to the device portion 111 along a shortest path, compared with the related art, and increasing a path for transferring power and signal. This will be described below with reference to FIGS. 3A and 3B.

FIG. 3A is a cross-sectional view conceptually illustrating the transfer of power and signal depending on paths in a semiconductor device according to the related art, and FIG. 3B is a cross-sectional view conceptually illustrating the transfer of power and signal depending on paths in a semiconductor device according to an example embodiment.

Referring to FIG. 3A, a semiconductor device according to the related art includes a semiconductor substrate 101, a first connection line 113 and a first pad portion 115 provided on a front surface 110 of the semiconductor substrate 101, and a second connection line 123 provided on a rear surface 120 and including a power distribution network PDN. In the related art, a pad portion for electrical connection to an external component is provided only on a side of the front surface 110, for example, only the first pad portion 115 is provided. According to the related art, a portion of first pads 115p of the first pad portion 115 is used to transfer a signal, and another portion thereof is used to transfer power.

In the semiconductor device according to the related art, a power distribution network PDN is additionally provided on the rear surface 120 of the semiconductor substrate 101 in the form of a second connection line 123 to improve efficiency of a space for placing a device portion 111, a first connection line 113 connected to the device portion 111, and a power distribution network PDN for supplying power to the device portion 111 on a side of the front surface 110 of the semiconductor substrate 101.

When a path for supplying power to the device portion 111 in the semiconductor device according to the related art is referred to as a first path PTH1, the power distribution network PDN is present on the rear surface 120 of the semiconductor substrate 101, so that the first path PTH1 may sequentially pass through the first pad portion 115, the first connection line 113, the through-substrate via TSV of the semiconductor substrate 101, the second connection line 123 corresponding to the power distribution network PDN, and another through-substrate via TSV of the semiconductor substrate 101 and then reach the device portion 111. In addition, when a path for providing signal to the device portion 111 in the semiconductor device according to the related art is referred to as a second path PTH2, the second path PTH2 may pass through the first pad portion 115 and the first connection line 113 and then reach the device portion 111. As described above, when power is transferred to the device portion 111 through the first path PTH1, a path is significantly long compared with a path for transferring a signal. In addition, in such a power transfer path according to the related art, there is a need to simultaneously transfer power from the front surface 110 to the rear surface 120 and transfer power from the rear surface 120 to the front surface 110, so that the number of through-substrate vias TSVs is naturally increasing. Thus, a burden on a manufacturing process was increased.

Moreover, an area of the front surface 110 of the semiconductor substrate 101 is limited, so that the number of the first pads 115p for transferring power should be decreased, a pitch of the first pads 115p should be reduced, or a size of the semiconductor substrate 101 itself should be increased, during a semiconductor device manufacturing process. For example, the pitch of the first pads 115p is inevitably affected by a size of the connector CNT that is subsequently in contact with the first pads 115p. Therefore, when a connector CNT such as a solder ball is used, adjacent solder balls need to be sufficiently spaced apart from each other. However, when the number of first pads 115p for power transmission is decreased, there may be an issue in the power supply to the device portion 111. In addition, when the pitch of the first pads 115p is reduced or the size of the semiconductor substrate 101 is increased, the manufacturing costs may be increased.

Referring to FIG. 3B, a semiconductor device according to an example embodiment may further include a second pad portion 125 on the rear surface 120 for electrically connection to the outside. Accordingly, the number of possible cases for a path of power and signal may be increased, and a length of the path may be significantly decreased. This will be described as follows.

When a path for supplying power to the device portion 111 is referred to as a first path PTH1 in the semiconductor device according to an example embodiment, the first path PTH1 may sequentially pass through the second pad portion 125, the second connection wiring 123 including the power distribution network PDN, the substrate through-silicon via TSV of the semiconductor substrate 101, and then reach the device portion 111. When a path for providing a signal to the device portion 111 is referred to as a second path PTH2, the second path PTH2 may pass through the first pad portion 115 and the first connection wiring 113, and then reach the device portion 111. In the semiconductor device according to an example embodiment, power may be directly transferred to the power distribution network PDN through the second pad portion 125. Thus, a length of the power transfer path to the device portion 111 may be significantly decreased, compared with the related art.

In addition, the semiconductor device according to an example embodiment may be provided with a first pad portion 115 and a second pad portion 125 on the front surface 110 and the rear surface 120, respectively, to have an additional signal or power transfer path. Accordingly, the degree of freedom in signal or power transfer may be increased. For example, a part of the second connection line 123 that is not used as the power distribution network PDN may be used as a path for transmitting signals (e.g., third path PTH3). The third path PTH3 may allow a signal to be transferred to the device portion 111 from the rear surface 120 of the semiconductor substrate 101 through the second pad portion 125, the second connection line 123, and the through-substrate via TSV. In addition, power may be supplied to the device portion 111 through the first path PTH1. In addition, a signal or power may be transferred from the rear surface 120 of the semiconductor substrate 101 to the front surface 110 of the semiconductor substrate 101, or vice versa, through the path passing through the second pad portion 125, the second connection line 123, the through-substrate via TSV, the first connection line 113, and the first pad portion 115. Such a path is indicated as a fourth path PTH4 in the drawings. When a signal or power is transferred through the fourth path PTH4, the signal or power may be processed through the device portion 111. In some example embodiments, the fourth path PTH4 may function only as a simple path through which the signal or power is transferred without passing through the device portion 111.

In addition, the semiconductor device according to an example embodiment may be provided with the first and second pad portions 115 and 125 on the front surface 110 and the rear surface 120, respectively, so that the number of pads for power transfer is not decreased, unlike the related art in which only the first pad portion 115 is provided in a limited area of the front surface 110 of the semiconductor substrate 101. Rather, the number of pads for power transfer may be increased to improve the efficiency of power distribution using the power distribution network PDN. In addition, a pitch of the pads may be maintained sufficiently or formed to be larger, and a size of the semiconductor substrate 101 itself may be reduced even with the increase in the number or pitch of the pads. Furthermore, in the power transfer path according to an example embodiment, it is sufficient to transfer power in only one direction between the front surface 110 and the rear surface 120. Thus, the number of through-substrate vias TSVs may also be significantly reduced compared with the related art, thereby reducing a burden of the manufacturing process.

Accordingly, the disclosed example embodiments are advantageous in reducing manufacturing costs and implementing a lightweight and compact semiconductor device. For example, when a semiconductor package including a semiconductor device is configured, a size of the semiconductor package may be significantly reduced by including a semiconductor device having sufficient pad portions for electrical connection on both the front and rear surfaces thereof. By having sufficient pad portions for electrical connection on both the front and rear surfaces of a semiconductor device, a size of the semiconductor device itself may also be reduced.

The semiconductor device according to an example embodiment having the above-described structure may be variously modified within the scope without departing from the inventive concepts. In the following example embodiments, differences from the above-described embodiments will be mainly described, and descriptions of the same or similar components will be omitted.

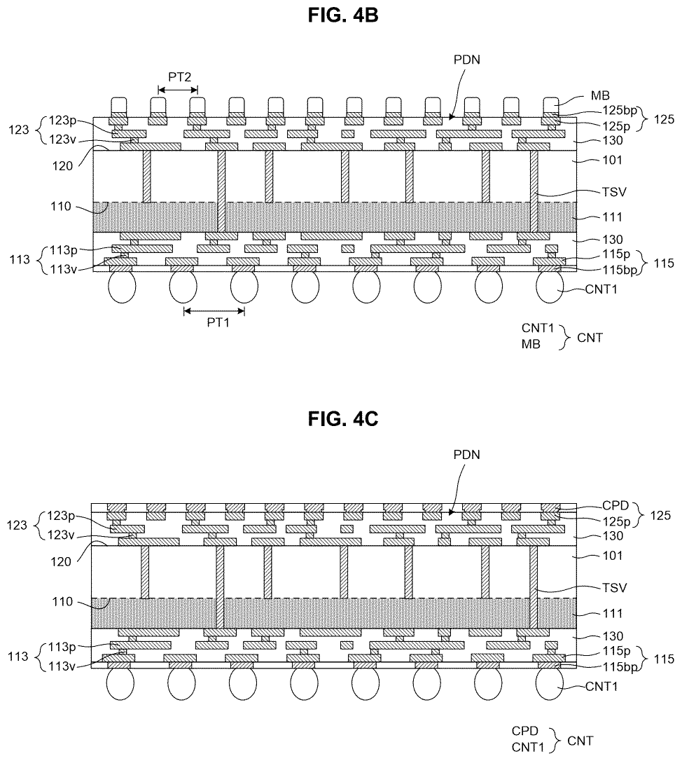

FIGS. 4A to 4C are cross-sectional views of semiconductor devices according to some example embodiments, which illustrate that the first pad portion 115, the second pad portion 125, and/or the connector CNT are formed to be different from those in the above-described example embodiments.

Referring to FIG. 4A, a connector CNT may be provided in a different manner on the first pad portion 115 and the second pad portion 125. For example, as illustrated, solder balls for C4 bumps are provided on the first pad portion 115 and the second pad portion 125 in the above-described example embodiments, but micro bumps (e.g., first micro bumps MB1 and second micro bumps MB2) may be provided on the first pad portion 115 and the second pad portion 125, respectively, in the present example embodiment. In an example embodiment, a pitch of the first micro bumps MB1 and a pitch of the second micro bumps MB2 may be the same or different from each other.

Referring to FIG. 4B, a connector CNT for connecting each of the first pad portion 115 and the second pad portion 125 to an external component may be different. For example, as illustrated, solder balls for C4 bumps may be provided on the first pad portion 115 as the first connector CNT1, and micro bumps MB may be provided on the second pad portion 125.

Pitches of the pads and connectors CNT on the first pad portion 115 and the second pad portion 125 may be different from each other. When a pitch of the first pads 115p and the first connector CNT1 on the first pad portion 115 is referred to as a first pitch PT1 and a pitch of the second pads 125p and the micro bumps MB on the second pad portion 125 is referred to as the second pitch PT2, the first pitch PT1 may have a value different from a value of the second pitch PT2. For example, the first pitch PT1 may have a larger value than the second pitch PT2.

In an example embodiment, the drawings illustrate that different types of connectors CNT are used depending on a difference in the pitch of the first pad portion 115 and the second pad portion 125. However, example embodiments are not limited thereto, and the same type of connector CNT may be used with only pitches of the first pad portion 115 and the second pad portion 125 being different from each other. For example, both the first pad portion 115 and the second pad portion 125 may be provided with solder balls for C4 bumps, but the pitches of the first pad portion 115 and the second pad portion 125 may be different from each other. In some example embodiments, both the first pad portion 115 and the second pad portion 125 may be provided with micro bumps MB, but the pitches of the first pad portion 115 and the second pad portion 125 may be different from each other.

Referring to FIG. 4C, instead of C4 bumps or micro bumps MB, other types of connectors CNT may also be used as a connector CNT for connection to an external component. In FIG. 4C, a metal bonding pad for metal-to-metal bonding may be provided on the second pad portion 125. For example, a copper bonding pad CPD for copper (Cu)-copper (Cu) bonding may be provided on the second pad portion 125. In the case of the copper bonding pad CPD, it may be manufactured by forming bonding pads with copper after forming pads, rather than an additional individual component as a connector CNT for connection to an external component. In the present embodiment, C4 bump solder balls are illustrated as being provided on the first pad portion 115 as the first connector CNT1, but example embodiments are not limited thereto, and the C4 bump solder balls may be provided with various pitches and various connectors CNTs in combination with the above-described example embodiments.

Although not illustrated, various connectors CNTs such as solder resist pillars and cored solder balls may be provided on the first pad portion 115 and the second pad portion 125. In this case, structures of the first pad portion 115 and the second pad portion 125 may be partially different for corresponding connectors CNTs.

The semiconductor device according to an example embodiment may also be provided in a structure in which a plurality of semiconductor chips are stacked.

In the case of a semiconductor chip according to an example embodiment, signal and power transfer paths may be formed in both front and rear directions. Therefore, even when a plurality of semiconductor chips are stacked, signal and power may be transferred over a shortest distance.

In an example embodiment, a plurality of stacked semiconductor chips may be of the same type or of different types. In the following example embodiments, for ease of description, stacked semiconductor chips are of the same type, but example embodiments are not limited thereto, and different types of semiconductor chips may be used in a stacked structure.

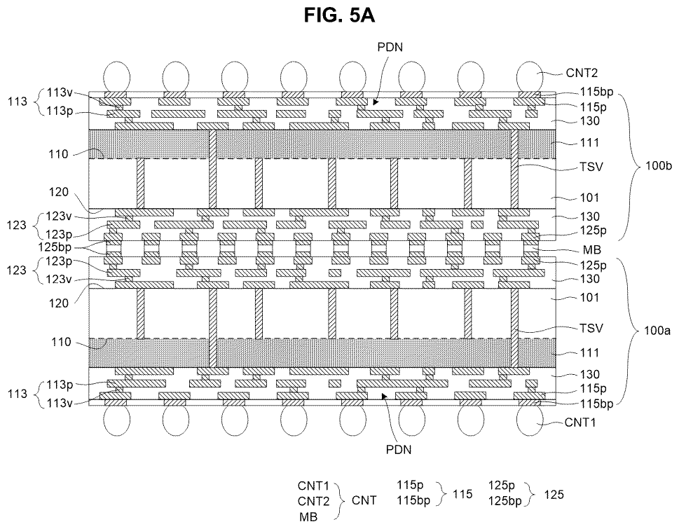

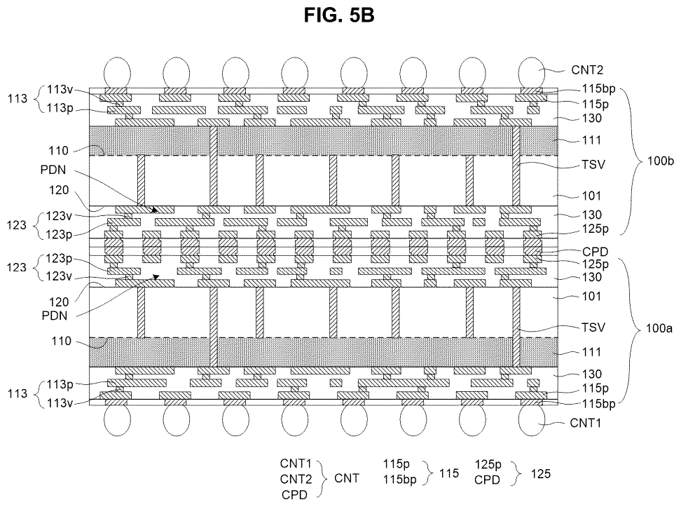

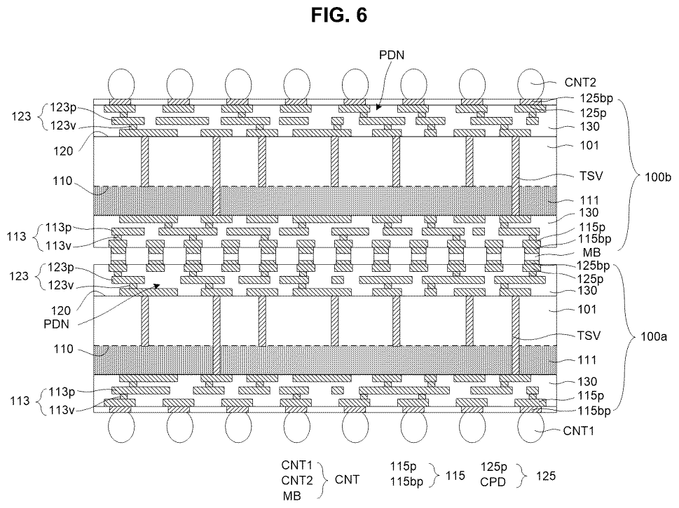

FIGS. 5A and 5B are cross-sectional views of an example of a semiconductor device according to some example embodiments in which two semiconductor chips are vertically stacked.

Referring to FIGS. 5A and 5B, when two stacked semiconductor chips are referred to as a first semiconductor chip 100a and a second semiconductor chip 100b, the second semiconductor chip 100b may be stacked on a first semiconductor chip 100a. In this case, one of the two stacked semiconductor chips may be flipped. For example, one of the two stacked semiconductor chips may have a structure in which a front surface 110 of the first semiconductor chip 100a opposes a front surface 110 of the second semiconductor chip 100b. Similar to the above-described example embodiment, the first semiconductor chip 100a may have the front surface 110, disposed on a lower side in the drawings, and the rear surface 120 disposed on an upper side in the drawings. On the other hand, the second semiconductor chip 100b may be flipped and disposed in an opposite direction of the first semiconductor chip 100a, so that the second semiconductor chip 100b may have a front surface 110 disposed on an upper side in the drawings, and a rear surface 120 disposed on a lower side in the drawings. Accordingly, a second connection line 123 and a second pad portion 125 of the first semiconductor chip 100a may oppose or face the second connection line 123 and the second pad portion 125 of the second semiconductor chip 100b.

Referring to FIGS. 5A and 5B, the first semiconductor chip 100a and the second semiconductor chip 100b may be stacked with a connector CNT interposed therebetween. For example, referring to FIG. 5A, micro bumps MB may be provided on the second pad portion 125 of the first semiconductor chip 100a and the second pad portion 125 of the second semiconductor chip 100b, as connectors CNT. Referring to FIG. 5B, a copper bonding pad CPD may be provided on the second pad portion 125 of the first semiconductor chip 100a and the second pad portion 125 of the second semiconductor chip 100b to connect the first pad portion 115 and the second pad portion 125 in a Cu—Cu bonding manner.

In FIGS. 5A and 5B, connectors CNT for connection to the outside may be provided on the first pad portion 115 disposed on a lowermost surface of the first semiconductor chip 100a and the first pad portion 115 disposed on an uppermost surface of the second semiconductor chip 100b, respectively. For example, the connectors CNT for connection to the outside may include a first connector CNT1, disposed on the lowermost surface of the first semiconductor chip 100a, and the second connector CNT2 disposed on an uppermost surface of the second semiconductor chip 100b. The first connector CNT1 and the second connector CNT2 may be provided in various forms of connectors CNT, for example, in the form of C4 solder balls, but example embodiments are not limited thereto.

Although not illustrated in FIG. 5A, an underfill material layer encompassing micro bumps MBs may be provided in a space between the first semiconductor chip 100a and the second semiconductor chip 100b. The underfill material layer may be formed of an epoxy resin formed by, for example, a capillary underfill method. In some example embodiments, the underfill material layer may be a non-conductive film (NCF).

In an example embodiment, the first semiconductor chip 100a and the second semiconductor chip 100b may be provided in a form, different from those in the above-described example embodiments.

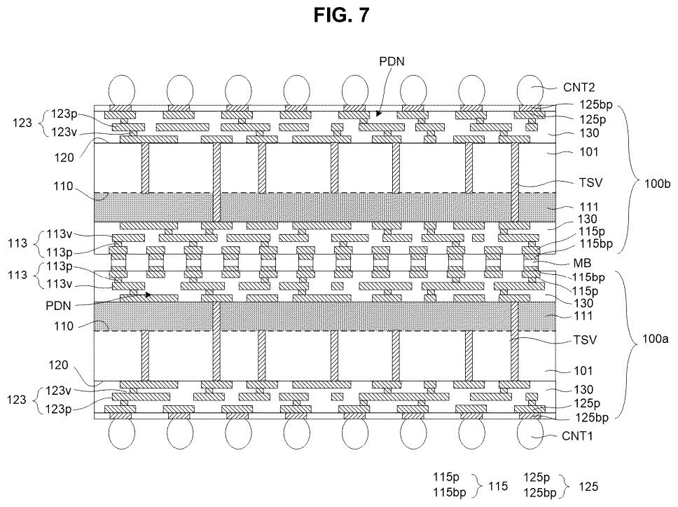

FIGS. 6 and 7 are cross-sectional views illustrating that a stacked structure of the first semiconductor chip 100a and the second semiconductor chip 100b is different from the stacked structure of the semiconductor device of FIGS. 5A and 5B, according to some example embodiments.

Referring to FIG. 6, the first semiconductor chip 100a and the second semiconductor chip 100b may be stacked such that front surfaces 110 of both semiconductor chips are disposed in the same direction without flipping. For example, the first semiconductor chip 100a may have the front surface 110 disposed on a lower side thereof and a rear surface 120 disposed on an upper side thereof. The second semiconductor chip 100b may also be disposed in the same direction as the first semiconductor chip 100a so that the second semiconductor chip 100b may have a rear surface 120 arranged on an upper surface thereof and a front surface 110 disposed on a lower surface thereof. Accordingly, the second connection line 123 and the second pad portion 125 of the first semiconductor chip 100a may oppose or face the first connection line 113 and the first pad portion 115 of the first semiconductor chip 100a.

Referring to FIG. 7, the second semiconductor chip 100b may be stacked on the first semiconductor chip 100a, and the first semiconductor chip 100a may be flipped and the second semiconductor chip 100b may not be flipped. For example, the first semiconductor chip 100a may have a front side 110 disposed on an upper side thereof and a rear surface 120 disposed on a lower side thereof. In contrast, the second semiconductor chip 100b may have a rear surface 120 disposed on an upper side thereof and a front surface 110 disposed on a lower side thereof. Accordingly, a first connection line 113 and a first pad portion 115 of the first semiconductor chip 100a may oppose a second connection line 123 and a second pad portion 125 of the first semiconductor chip 100a.

In FIGS. 6 and 7, connectors CNT for connection to the outside may be provided on pad portions disposed on a lower surface of the first semiconductor chip 100a and an upper surface of the second semiconductor chip 100b, respectively. In the example embodiments of FIGS. 6 and 7, the connectors CNT for connection to the outside may include the first connector CNT1, disposed on a lower surface of the first semiconductor chip 100a, and the second connector CNT2 disposed on an upper surface of the second semiconductor chip 100b. The first connector CNT1 and the second connector CNT2 may be provided in various forms of connectors CNT, for example, in the form of 4C solder balls, but example embodiments are not limited thereto.

As illustrated in FIGS. 5A, 6, and 7, a stacked structure of a plurality of semiconductor chips in a semiconductor device according to some example embodiments may include a face-to-face, face-to-back, and back-to-back stacked structures.

While an example in which semiconductor chips having the same size are stacked is provided in the above-described embodiments, the sizes of the semiconductor chips are not limited thereto.

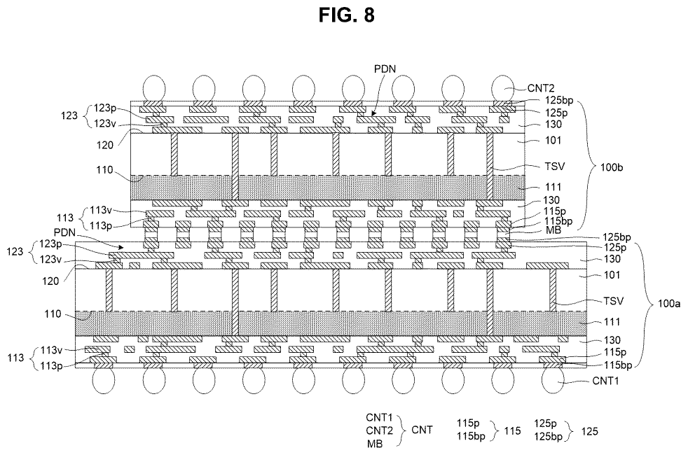

FIG. 8 is a cross-sectional view of a semiconductor device according to an example embodiment, which illustrates a cross-section in which two semiconductor chips having different sizes are stacked.

Referring to FIG. 8, as described above, a plurality of stacked semiconductor chips may be of the same type or different types. In addition, the plurality of stacked semiconductor chips may have different sizes. For example, when a first semiconductor chip 100a and a second semiconductor chip 100b are sequentially stacked, a size of the underlying first semiconductor chip 100a may be larger than a size of the overlying second semiconductor chip 100b. In this case, when viewed in plan view, the second semiconductor chip 100b may be disposed to completely overlap the first semiconductor chip 100a, or may be disposed to partially overlap the first semiconductor chip 100a even when it does not completely overlap the first semiconductor chip 100a.

In addition, in the present example embodiment, a connector CNT between the first semiconductor chip 100a and the second semiconductor chip 100b is illustrated as an example of micro bumps MB, but example embodiments are not limited thereto. The first semiconductor chip 100a and the second semiconductor chip 100b may use various other connectors CNTs described above. In addition, for example, a plurality of wires may be used to electrically connect the first semiconductor chip 100a and the second semiconductor chip 100b.

A semiconductor chip in a semiconductor device according to an example embodiment may include pad portions for connection to the outside provided on both a front surface 110 and a rear surface 120, respectively, to achieve power transfer to a device portion 111 through a power distribution network PDN provided on a rear surface 120 of each semiconductor chip and to easily achieve signal transfer through pad portions disposed on the front surface 110 and the rear surface 120 in a shortest distance. For example, even when a plurality of semiconductor chips are stacked, power transfer and signal transfer in a vertical direction may be implemented through pad portions on opposite surfaces of a semiconductor chip, connection lines, and through-substrate vias TSVs penetrating through a front surface 110 and a rear surface 120 of each semiconductor chip.

According to an example embodiment, a semiconductor device having a plurality of stacked semiconductor chips may be implemented as a semiconductor package.

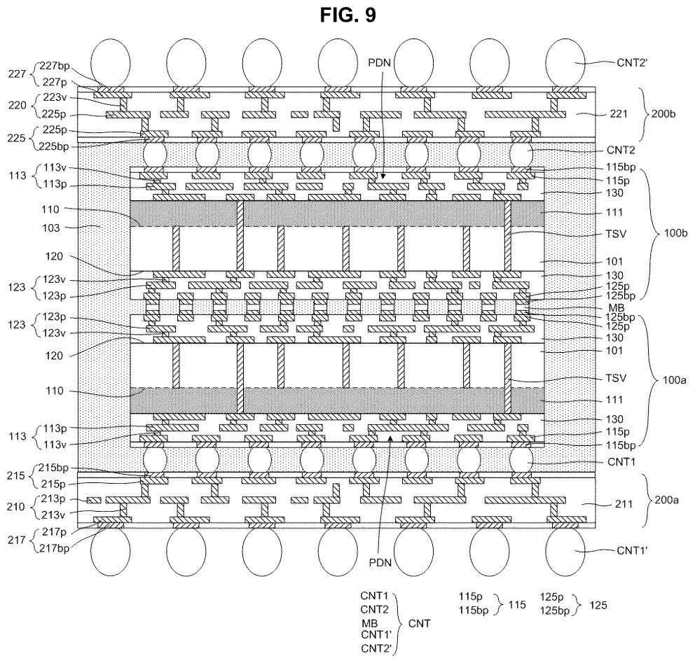

FIG. 9 is a cross-sectional view of a semiconductor package according to an example embodiment.

Referring to FIG. 9, the semiconductor package according to an example embodiment may include a first package substrate 200a and a second package substrate 200b, opposing each other, and a semiconductor device provided between the first package substrate 200a and the second package substrate 200b.

The first package substrate 200a may include a redistribution structure including at least one layer. The redistribution structure of the first package substrate 200a may include a first core layer 211 and a first redistribution line 210 provided within the first core layer 211.

The first redistribution line 210 may include a first redistribution pattern 213p, and a first redistribution via 213v penetrating through the first core layer 211. The first redistribution pattern 213p may be provided to transfer an electrical signal and power in a lateral direction, and the first redistribution via 213v may be provided to transfer an electrical signal and power in a vertical direction. The first redistribution pattern 213p and the first redistribution via 213v may be provided in plural for each layer.

The redistribution structure of the first package substrate 200a may be provided with a first internal pad portion 215 disposed on a side opposing the semiconductor device, and a first external pad portion 217 disposed on an opposite side of the first internal pad portion 215. The first internal pad portion 215 may include a first internal pad 215p and a first internal bonding pad 215bp, and the first external pad portion 217 may include a first external pad 217p and a first external bonding pad 217bp.

The second package substrate 200b may also include a redistribution structure including at least one layer. The redistribution structure of the second package substrate 200b may include a second core layer 221 and a second redistribution line 220 provided within the second core layer 221.

The second redistribution line 220 may include a second redistribution pattern 223p, and a second redistribution via 223v penetrating through the second core layer 221. The second redistribution pattern 223p may be provided to transfer an electrical signal and power in the lateral direction, and the second redistribution via 223v may be provided to transfer an electrical signal and power in the vertical direction. The second redistribution pattern 223p and the second redistribution via 223v may be provided in plural for each layer.

The redistribution structure of the second package substrate 200b may be provided with a second internal pad portion 225 disposed on a side opposing the semiconductor device, and a second external pad portion 227 disposed on an opposite side of the second internal pad portion 225. The second internal pad portion 225 may include a second internal pad 225p and a second internal bonding pad 225bp, and the second external pad portion 227 may include a second external pad 227p and a second external bonding pad 227bp.

The first redistribution pattern 213p, the second redistribution pattern 223p, the first redistribution via 213v, and the second redistribution via 223v may be formed of various conductive materials such as tungsten, cobalt, nickel, copper, silver, gold, zinc, platinum, aluminum, or combinations thereof. However, the conductive material is not limited thereto and may include, for example, electrolytically deposited (ED) copper foil, rolled-annealed (RA) copper foil, stainless steel foil, aluminum foil, ultra-thin copper foils, sputtered copper, copper alloys, or the like.

Each of the first and second core layers 211 and 221 may be formed of at least one material selected from the group consisting of phenolic resin, epoxy resin, and polyimide. The first and second core layers 221 may include at least one material selected from the group consisting of Flame Retardant 4 (FR-4), tetrafunctional epoxy, polyphenylene ether, epoxy/polyphenylene oxide, bismaleimide triazine (BT), Thermount, cyanate ester, polyimide, or liquid crystal polymer.

In an example embodiment, a first package substrate 200a and a second package substrate 200b may be printed circuit boards. However, the types of the first package substrate 200a and the second package substrate 200b are not limited thereto, and the first package substrate 200a and the second package substrate 200b may be provided in various substrates on which at least one semiconductor chip may be mounted. For example, the first package substrate 200a and/or the second package substrate 200b may be a wafer-level substrate with devices formed on a wafer.

A semiconductor device may include one or more semiconductor chips. As illustrated in the drawing, the semiconductor device may include two sequentially stacked semiconductor chips, for example, the first semiconductor chip 100a and the second semiconductor chip 100b. The first semiconductor chip 100a and the second semiconductor chip 100b may be connected to each other by micro bumps MBs provided between the first semiconductor chip 100a and the second semiconductor chip 100b.

Connectors CNTs for connection to the first package substrate 200a and the second package substrate 200b may be provided on pad portions disposed on a lowermost surface of the first semiconductor chip 100a and an uppermost surface of the second semiconductor chip 100b. In the present embodiment, a first connector CNT1 may be provided between the first package substrate 200a and the first semiconductor chip 100a to connect the first package substrate 200a and the first semiconductor chip 100a. A second connector CNT2 may be provided between the second package substrate 200b and the second semiconductor chip 100b to connect the second package substrate 200b and the second semiconductor chip 100b.

Connectors CNTs for connection to external components may be provided on external sides of the first package substrate 200a and the second package substrate 200b. The connectors CNTs for connection to the external components may include a first external connector CNT1′, disposed on a lowermost surface of the first package substrate 200a, and a second external connector CNT2′ disposed on an uppermost surface of the second package substrate 200b. The first external connector CNT1′ and the second external connector CNT2′ may be provided in various forms of connectors, for example, in the form of 4C solder balls, but example embodiments are not limited thereto.

In an example embodiment, a package molding layer 103 may be provided between the first package substrate 200a and the second package substrate 200b. The package molding layer 103 may be formed of a polymer material such as epoxy molding compound (EMC). However, example embodiments are not limited thereto, and the package molding layer 103 may include various materials such as an epoxy-based material, a thermosetting material, a thermoplastic material, or a UV curable material.

The semiconductor package according to an example embodiment may be a chiplet type semiconductor package including at least two semiconductor chips, for example, a chiplet type semiconductor package module including at least two semiconductor chips, at least two semiconductor packages, or an interposer on a package substrate. Semiconductor chips and semiconductor packages may be 3-diomensinally stacked to constitute a 3D semiconductor package module. In some example embodiments, among two or more semiconductor chips, at least one semiconductor chips may be disposed on an interposer and the remaining semiconductor chips may be disposed on a package substrate to constitute a 2.5D semiconductor package module. In some example embodiments, semiconductor chips may be disposed only on a package substrate to constitute a 2D semiconductor package module. Furthermore, 3D, 2.5D, and 2D semiconductor packages may be mixed to constitute a hybrid semiconductor package module.

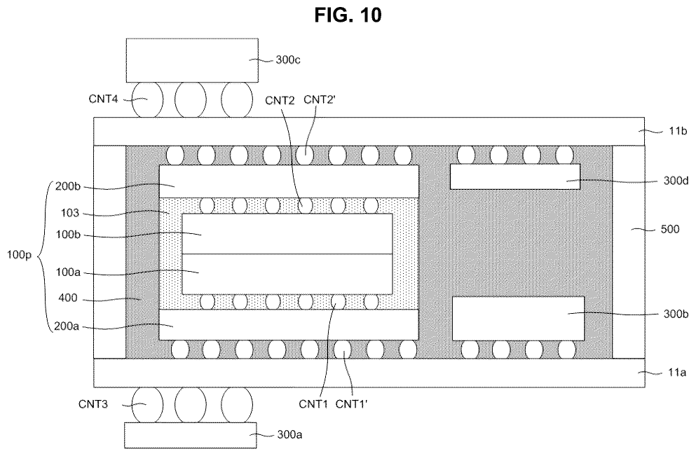

FIG. 10 is a conceptual diagram illustrating a semiconductor package module according to an example embodiment.

Referring to FIG. 10, a semiconductor package module according to an example embodiment may include a first module substrate 11a and a second module substrate 12a, opposing each other, and at least one semiconductor package stacked on the first module substrate 11a and the second module substrate 12a.

Each of the first module substrate 11a and the second module substrate 12a may be a substrate on which various semiconductor packages may be mounted, and may be provided in various forms. For example, each of the first module substrate 11a and the second module substrate 12a may be a printed circuit board. However, the types of the first module substrate 11a and the second module substrate 12a are not limited thereto, and the first module substrate 11a and the second module substrate 12a may be provided in various substrates on which at least one semiconductor chip may be mounted. For example, the first module substrate 11a and/or the second module substrate 12a may be a wafer-level substrate with devices formed on a wafer.

A molding layer 400, formed of or including a material such as a thermosetting resin, may be provided between the first module substrate 11a and the second module substrate 12a. The molding layer 400 may be formed of or include a polymer material such as epoxy molding compound (EMC). However, example embodiments are not limited thereto, and the molding layer 400 may include various materials such as an epoxy-based material, a thermosetting material, a thermoplastic material, or a UV curable material.

In the present example embodiment, the semiconductor package may include a single semiconductor chip or a plurality of semiconductor chips stacked. The semiconductor package may be provided in plural. In the present example embodiment, five semiconductor packages, for example, first to fifth semiconductor packages 100p, 300a, 300b, 300c, and 300d, are illustrated as being provided in a single semiconductor package module.

The semiconductor packages 100p, 300a, 300b, 300c, and 300d may be provided between the first module substrate 11a and the second module substrate 12a, and may also be provided on an external side surface of the first module substrate 11a and/or an external side surface of the second module substrate 12a.

For example, the first to third semiconductor packages 100p, 300a, and 300b may be disposed on the first module substrate 11a. The first semiconductor chip 100p may be disposed between the first module substrate 11a and the second module substrate 12a to be connected to the first module substrate 11a through a first external connector CNT1′ and to be connected to the second module substrate 12a through a second external connector CNT2′. The second semiconductor package 300a may be connected to the external side surface of the first module substrate 11a through a lower connector CNT3, and the third semiconductor package 300b may be connected to an internal side surface of the first module substrate 11a through the first external connector CNT1′.

In addition to the first semiconductor package 100p described above, a fourth semiconductor package 300c and a fifth semiconductor package 300d may be disposed on the second module substrate 12a. The fourth semiconductor package 300c may be connected to an external side surface of the second module substrate 12a through an upper connector CNT4, and the fifth semiconductor package 300d may be connected to an internal side surface of the second module substrate 12a through a second external connector CNT2′.

In an example embodiment, a first semiconductor package 100p may be the semiconductor chip(s) according to the above-described example embodiments, or a semiconductor package including the semiconductor chip(s) according to the above-described example embodiments. For example, the first semiconductor package 100p may be the semiconductor package illustrated in FIG. 9.

The first semiconductor package 100p may include a first semiconductor chip 100a and a second semiconductor chip 100b provided between a first package substrate 200a and a second package substrate 200b, and the first semiconductor chip 100a and the second semiconductor chip 100b may be connected to the first package substrate 200a and the second package substrate 200b through the first connector CNT1 and the second connector CNT2, respectively.

In an example embodiment, the first to fifth semiconductor packages 100p, 300a, 300b, 300c, and 300d may be IC semiconductor packages including various integrated circuit chips (e.g., logic semiconductor chips, memory semiconductor chips, or combinations thereof).

In an example embodiment, at least one of the second to fifth semiconductor packages 300a, 300b, 300c, and 300d may be a power management integrated circuit (PMIC) semiconductor package including a PMIC chip. For example, one of the second semiconductor package 300a and the third semiconductor package 300b, provided on the first module substrate 11a, and one of the fourth semiconductor package 300c and the fourth semiconductor package 300c, provided on the second module substrate 12a, may include a PMIC chip. In an example embodiment, each of the second semiconductor package 300a and the fourth semiconductor package 300c may include a PMIC chip.

One of the second semiconductor package 300a and the third semiconductor package 300b, provided on the first module substrate 11a, may be provided as a PMIC chip to easily implement power distribution (e.g., power distribution to the first semiconductor chip 100a in the first semiconductor package 100p) through the first module substrate 11a. In addition, one of the fourth semiconductor package 300c and the fourth semiconductor package 300c, provided on the second module substrate 12a, may be provided as a PMIC chip to easily implement power distribution to the second semiconductor package 300a (e.g., power distribution to the second semiconductor chip 100b in the second semiconductor package 300a) through the second module substrate 12a. In such a manner, power may be supplied to the first semiconductor package 100p from both an upper side and a lower side of the first semiconductor package 100p at the same time, so that routing complexity of a power supply interconnection may be significantly reduced.

In an example embodiment, an electrical connection member, for example, an interposer 500, may be provided between the first module substrate 11a and the second module substrate 12a. As desired, the first module substrate 11a and the second module substrate 12a may be directly electrically connected using other electrical connection members such as conductive pillars or wire connections, other than the interposer 500. However, a signal or power may be easily transferred between the semiconductor package and the first module substrate 11a and the second module substrate 12a as in the first semiconductor package 100p, so that the connection components such as the interposer, the conductive pillars, and the wire connections may be omitted depending on the situation.

As set forth above, some example embodiments provide semiconductor devices for providing power and signals to a semiconductor chip and semiconductor packages including the same.

While some example embodiments have been shown and described above, it will be apparent to those skilled in the art that modifications and variations could be made without departing from the scope of the present inventive concepts as defined by the appended claims.

What is claimed is:

1. A semiconductor device comprising at least one semiconductor chip, wherein
the semiconductor chip comprises:
a semiconductor substrate having a front surface and a rear surface;
a device portion on the front surface;
a first connection line on the device portion;
a first pad portion on the first connection line and comprising a plurality of first pads;
a second connection line on the rear surface and comprising a power distribution network; and
a second pad portion on the second connection line and comprising a plurality of second pads, and
at least a portion of the second pads is connected to the power distribution network to apply power supply voltage to the device portion through the power distribution network.

2. The semiconductor device of claim 1, wherein
the semiconductor substrate comprises at least one through-substrate via penetrating through the front surface and the rear surface of the semiconductor substrate and connecting the second connection line and the device portion to each other and the second connection line and the first connection line to each other.

3. The semiconductor device of claim 1, wherein
each of the first connection line and the second connection line comprises conductive interconnections on at least one layer and conductive vias connecting the conductive interconnections to each other.

4. The semiconductor device of claim 1, further comprising:
first connectors on the first pad portion configured to be connected to an external component; and
second connectors on the second pad portion configured to be connected to an external component.

5. The semiconductor device of claim 4, wherein
a pitch of the first connectors is different from a pitch of the second connectors.

6. The semiconductor device of claim 4, wherein
the first connectors and the second connectors comprise one of C4 bumps, micro bumps, conductive pillars, solder balls for ball grid array, cored solder balls, or copper-cupper bonding.

7. A semiconductor device comprising:
a first semiconductor chip and a second semiconductor chip stacked sequentially,
wherein each of the first semiconductor chip and the second semiconductor chip comprises,
a semiconductor substrate having a front surface and a rear surface,
a device portion on the front surface,
a first connection line on the device portion,
a first pad portion on the first connection line and comprising a plurality of first pads,
a second connection line on the rear surface and comprising a power distribution network, and
a second pad portion on the second connection line and comprising a plurality of second pads, and
at least a portion of the second pads is connected to the power distribution network to apply a power supply voltage to the device portion through the power distribution network.

8. The semiconductor device of claim 7, further comprising:
a first connector on the first pad portion; and
a second connector on the second pad portion,
wherein the first connector and the second connector comprise one of C4 bumps, micro bumps, conductive pillars, solder balls for ball grid array, cored solder balls, or copper-cupper bonding.

9. The semiconductor device of claim 7, wherein
the first semiconductor chip and the second semiconductor chip are stacked such that a front surface of the first semiconductor chip and a front surface of the second semiconductor chip oppose each other.

10. The semiconductor device of claim 7, wherein
the first semiconductor chip and the second semiconductor chip are stacked such that a rear surface of the first semiconductor chip and a front surface of the second semiconductor chip oppose each other.

11. The semiconductor device of claim 7, wherein
the first semiconductor chip and the second semiconductor chip are stacked such that a rear surface of the first semiconductor chip and a rear surface of the second semiconductor chip oppose each other.

12. The semiconductor device of claim 7, wherein
the first semiconductor chip and the second semiconductor chip have different sizes.

13. A semiconductor device package comprising:
a first package substrate;
a second package substrate; and
at least one semiconductor chip between the first package substrate and the second package substrate,
wherein the at least one semiconductor chip comprises,
a semiconductor substrate having a front surface and a rear surface,
a device portion on the front surface,
a first connection line on the device portion,
a pad portion on the first connection line and comprising a plurality of first pads,
a second connection line on the rear surface and comprising a power distribution network, and
a second pad portion on the second connection line and comprising a plurality of second pads, and
at least a portion of the second pads is connected to the power distribution network to apply a power supply voltage to the device portion through the power distribution network.

14. The semiconductor device package of claim 13, wherein
the at least one semiconductor chip includes a first semiconductor chip and a second semiconductor chip,
the first semiconductor chip and the first package substrate are connected by a connector, and
the second semiconductor chip and the second package substrate are connected by a connector.

15. The semiconductor device package of claim 13, further comprising:
a molding layer filling a space between the first package substrate and the second package substrate.

16. The semiconductor device package of claim 13, wherein
at least one of the first package substrate or the second package substrate comprises a redistribution structure and external connectors connected to the redistribution structure.

17. A semiconductor package module comprising:
a first module substrate;
a second module substrate;
the semiconductor device package of claim 13 between the first module substrate and the second module substrate; and
at least one semiconductor package on at least one of the first module substrate or the second module substrate.

18. The semiconductor package module of claim 17, further comprising:
an interposer substrate
between the first module substrate and the second module substrate and connecting the first module substate and the second module substrate.

19. The semiconductor package module of claim 17, wherein
each of the first module substrate and the second module substrate is a printed circuit board.

20. The semiconductor package module of claim 17, wherein
the semiconductor package comprises a first power management integrated circuit (PMIC) on the first module substrate and a second PMIC on the second module substrate.
